(19) United States
(12) Patent Application Publication
(10) Pub. No.: US 2015/0101849 A1
(43) Pub. Date: Apr. 16, 2015

(54) TEMPERATURE-RESISTANT, TRANSPARENT ELECTRICAL CONDUCTOR, METHOD FOR THE PRODUCTION THEREOF, AND USE THEREOF

(71) Applicant: SCHOTT AG, Mainz (DE)

(72) Inventors: Matthias Bockmeyer, Mainz (DE); Ulf Hoffmann, Pfungstadt (DE); Franziska Riethmueller, Frankfurt (DE)

(21) Appl. No.: 14/513,274

(22) Filed: Oct. 14, 2014

(30) Foreign Application Priority Data
Oct. 11, 2013 (DE) 10 2013 111 267.6

(51) Int. Cl. H05K 1/02; H05K 3/14; H05K 3/46; H05K 3/12; H05K 1/09; H05K 1/03

(52) U.S. Cl. CPC H05K 1/0274; H05K 1/097; H05K 1/0306; H05K 3/4664; H05K 3/1216; H05K 3/125; H05K 3/1291; H05K 3/14; B33Y 80/00; B33Y 10/00; Y10S 977/932; B82Y 30/00
USPC 174/257; 427/96.1; 427/99.2; 427/98.4; 427/97.1; 977/932; 977/834

(57) ABSTRACT

A transparent electrical conductor with a transparent substrate and an electrically conductive layer on the substrate are provided. The conductive layer has a plurality of electrically conductive nanoscale additives. The additives are in electrically conductive contact with one another, in order to form the electrically conductive layer. The substrate is formed from a glass or glass-ceramic material or a composite material having a glass and/or glass-ceramic. The additives are embedded in a matrix layer at least in some regions. The matrix layer is formed by a transparent matrix material. In order to make such a transparent electrical conductor useful, particularly for application in a display, as a touch sensor, or the like for cooking surfaces, the transparent electrical conductor exhibits a temperature resistance of at least 140° C. The additives are dispersed in a matrix material, which is applied as a coating material onto the substrate in one coating step.

### CROSS REFERENCE TO RELATED APPLICATIONS

This application claims benefit under 35 U.S.C. §119(a) of German Patent Application No. 10 2013 111 267.6 filed Oct. 11, 2013, the entire contents of which are incorporated herein by reference.

### BACKGROUND

1. Field of the Disclosure

The invention relates to a transparent electrical conductor with a transparent substrate and a conductive layer on the substrate, said conductive layer having a plurality of electrically conductive, nanoscale additives, said additives being in electrically conductive contact with one another in some regions in order to form an electrically conductive layer, said substrate being formed from a glass or glass-ceramic material or from a composite material having a glass and/or glass ceramic, said additives being embedded in a matrix layer at least in some regions, and said matrix layer being formed from a transparent matrix material.

2. Description of Related Art

A transparent electrical conductor is composed of a transparent substrate material on which a transparent conductive layer is applied. The transparent conductive layer is characterized in this case by a good electrical conductivity with, at the same time, the existence of a high transmittance for light in the visible wavelength region. The electrical conductors can be incorporated as transparent electrodes in LCD displays, touch panels, photovoltaic cells, antistatic coatings, and EMC coatings.

Known from the prior art are transparent electrical conductors whose fabrication involves the application of a liquid, which contains electrically conductive nanoscale additives, onto a substrate surface. According to U.S. Pat. No. 8,049,333 B2, metallic nanowires are utilized, in particular, as additives. Subsequently, the liquid is evaporated, so that the additives lie on the substrate in the form a network. Afterwards, according to

U.S. Pat. No. 8,049,333 B2, a matrix material is applied onto the additive layer. The matrix material can then be pressed mechanically into the additive layer. Afterwards, the matrix material is cured. Relatively great technical effort is required to carry out the method described in U.S. Pat. No. 8,049,333 B2, particularly to the effect that, first of all, the additive layer and subsequently, in a second coating step, a protective matrix, are applied. Moreover, the electrical conductors that are fabricated using the method described in this document do not have the long-term stability and temperature resistance required for certain applications, particularly owing to high temperature effects.

Also known from the prior art are cooktops in which electrical heating elements are arranged beneath a panel made of glass or glass ceramics. Furthermore, displays or touch sensors are arranged on the back side of the glass or glass-ceramic panel. In this case, for example, ITO coatings or layers made of other transparent conductive oxides are applied to the back side of the glass or glass-ceramic panel by a sputtering or liquid-coating method. For example, a method for producing a coating with tin-doped indium oxide (ITO, indium tin oxide) is described in U.S. Pat. No. 7,309,405. Such a layer has a high transmittance and a good electrical conductivity and can be applied to the bottom side of the glass ceramic via a sputtering method. The technical effort involved in producing such layers is also quite high. On account of the declining availability of indium, material price increases are to be anticipated and cast further doubt on the usefulness of this method.

Described in JP 2010 092 650 is a cooktop that has a touch panel on the back side of the cooking panel, the touch field being composed of a transparent conductive layer, which is composed of a semiconductor oxide and an additional transparent protective layer.

DE 10 2009 053 688 discloses a transparent, conductive coating solution for screen printing. It is mixed with indium and a tin compound and is suitable for the formation of ITO layers. Such coating solutions exhibit a sheet resistance that is too high. The coatings have to be baked in, so that it is not possible to use a prestressed glass substrate. Furthermore, the layer cannot be baked in during a thermal prestressing process.

Finally, in the case of cooktop applications, the printing of films having conductive structures is known. Such films can then be laminated onto the bottom side of the cooktop. In the process, of course, there is the risk that delamination can occur if the adhesive fails upon interaction with the atmosphere. Furthermore, it requires great effort to bond the film to the bottom side of the cooktop without creating bubbles.

### SUMMARY

An object of the invention is to provide a transparent electrical conductor of the kind described initially that has a sufficiently high service life even under the effect of high temperature. Furthermore, an object of the invention is to produce a transparent electrical conductor by a simple method, preferably one involving only one coating step per transparent conductive layer.

This object is solved in that the substrate material and the matrix material are composed of materials that exhibit a temperature resistance of at least 140° C. This enables the creation of a transparent electrical conductor that is suitable for cooktop applications, in particular, and can be utilized in this case particularly in the cool region of a cooktop. It can be incorporated there for the creation of a display or a touch sensor. A hot or overheated pot that is placed on the top side of the cooktop does not damage the transparent electrical conductor. Instead, the latter exhibits a sufficiently high durability and resistance.

Preferably, the substrate and the matrix material exhibit a temperature resistance of at least 140° C., preferably at least 180° C., more preferably at least 200° C., so that the electrical conductor can be positioned, in particular, in the cool region of a cooking surface.

In accordance with a preferred variant of the invention, it may be provided that the scratch resistance of the matrix material is at least 500 g, preferably at least 700 g, as measured by the sclerometer test (Elcometer 3092 hardness testing rod with a 1.0-mm tungsten carbide tip). In this way, it is ensured that the transparent electrical conductor exhibits a sufficiently high mechanical strength. In particular, it is then scratch-resistant. This is particularly advantageous for cooking surfaces, because they may be subjected to high mechanical loads in the process of installing the cooking surface in the range. Thus, for example, it may occur that the sharp edges of the metal holders come into contact with the coating during this process.

Furthermore, the transparent electrical conductors also should exhibit a sufficient resistance to steam when they are used in a cooking surface, because steam can be highly corrosive. Therefore, for application in a cooking surface, the matrix material shall be chosen such that a resistance to steam for up to one hour is ensured (tested using a pot containing boiling water). Moreover, resistance to aging should also be afforded, with the sheet resistance of the electrical conductor increasing by no more than 25%, preferably by no more than 10%, over 10 years.

Particularly for use in displays, the matrix material should exhibit a light transmittance in the visible region (400 nm≦λ≦700 nm) of greater than 90%, preferably greater than 95% (in accordance with ASTM D 1003).

In order to prevent the transparency from being disrupted too much by the transparent electrical conductor, the haze value of the matrix material should be less than 5%, preferably less than 3%, more preferably less than 1%. The haze value is a measure of the haze of transparent specimens. This value describes the proportion of the transmitted light that is scattered or reflected by the irradiated specimen. Thus, the haze value quantifies material flaws in the surface of the matrix material or in its structure.

Nanowires or nanotubes, for example, can be utilized as conductive additives. They guarantee a good electrical conductivity with retention of a high transmission on account of their nanoscale dimensions. Defined as being nanoscale in this case are additives whose size is 200 nanometers or less in at least one dimension. The combination of fiber-like conductive additives with the small nanoscale diameter thereof enables the formation of conductive networks. The electrical resistance in this case can be adjusted in a controlled manner through the quantity of conductive additives. Whereas very high additive dosings (up to 50 weight %) are necessary to create conductivity paths when additives having a low aspect ratio are used, the so-called percolation threshold, that is, the critical concentration of additives at which the conductivity of the (layer) material rises abruptly, is at markedly lower concentrations for additives with a high aspect ratio.

Suitable matrix materials are, for example, UV-curable or thermally curable polymers, UV-crosslinkable or thermally organically crosslinkable hybrid-polymeric sol-gel materials, hybrid-polymeric sol-gel materials, nanoparticle-functionalized sol-gel materials, sol-gel materials with nanoparticle fillers, and/or inorganic sol-gel materials.

For the production of a transparent electrical conductor with a transparent conductive layer according to the invention, the highly conductive additives are dispersed in a liquid matrix precursor and, together with the matrix material, are applied onto the substrate in one coating step. In the process, the matrix is constituted such that the highly conductive additives can be dispersed in it. At the same time, however, the matrix does not fully surround the conductivity additives, so that the matrix does not electrically insulate the conductivity additives from one another.

The temperature resistance of the matrix material can be tested in annealing tests at the respective temperatures (in accordance with the invention, ≧140° C.) for 2 hours. In a special embodiment of the invention, the matrix protects the highly conductive additives against degradation (protection against oxygen, sulfur, H₂O, acid attack) or corrosion. In this way, the long-term stability of the conductivity of the coated substrate is ensured.

Preferably, for the production of an electrical conductor according to the invention, the substrate is coated with a coating solution, such as, for example, a screen-printing ink, composed of a matrix-forming material and highly conductive additives and, if need be, further added substances (dispersants, surface reactants (surfactants), solvents, thickeners, flow-control agents, deaerators, defoamers, curing agents, initiators, corrosion inhibitors, adhesion agents . . . ).

High-boiling solvents having a low vapor pressure of <5 bars, preferably <1 bar, more preferably <0.1 bar, can be utilized as solvents. Solvents that have a boiling point greater than 120° C. and an evaporation number of >10 are preferably added. Preferably, a solvent with a boiling point greater than 150° C. and an evaporation number of >500, more preferably with a boiling point greater than 200° C. and an evaporation number of >1000, is used. Such high-boiling solvents are, in particular, glycols and glycol ethers, terpenes, and polyols as well as mixtures of a plurality of these solvents. It is possible to use the following as solvents: butyl acetate, methoxybutyl acetate, 2-(2-butoxyethoxyl)ethyl acetate (carpitol acetate), 2-butoxyethyl acetate, butylcarbitol acetate F4789, butyl diglycol, butyl diglycol acetate, butyl glycol, butyl glycol acetate, cyclohexanone, diacetone alcohol, diethylene glycol, dipropylene glycol monomethyl ether, dipropylene glycol monobutyl ether, propylene glycol monobutyl ether, propylene glycol monopropyl ether, propylene glycol monoethyl ether, ethoxypropyl acetate, hexanol, 1,3-diethoxy-2-propanol, 1,5-pentandiol, 1-methoxy-2-propanol, 4-hydroxy-4-methyl-2-pentanone, ethyl acetoacetate, N,N-dimethylacetamide, polyethylene glycol 200, propylene carbonate, methoxypropyl acetate, monoethylene glycol, ethylpyrrolidone, methylpyrrolidone, dipropylene glycol dimethyl ether, propylene glycol, propylene glycol monomethyl ether, mixtures of paraffinic and naphthenic hydrocarbons, aromatic hydrocarbon mixtures, mixtures of aromatic alkylated hydrocarbons, and mixtures of n-, i-, and cyclo-aliphatic compounds. In particular, polyethylene glycol ethers, such as, for example, diethylene glycol monoethyl ether, tripropylene glycol monomethyl ether, and terpineol, can be used as solvent. Furthermore, mixtures of two or more of these solvents can be used. In the process, the solvents can be added both to the matrix precursors as well as the solution of the nanoscale additives.

In order to enable the coating material, in particular the coating solution, to be applied by various application and printing methods, the nanoscale additives and/or the matrix material are both present as matrix precursor prior to being combined in the coating material in at least one low-boiling solvent, in at least one high-boiling solvent, or in a solvent mixture composed of at least one low-boiling solvent and at least one high-boiling solvent. Low-boiling solvents have a boiling point of less than 120° C. and high-boiling solvents have a boiling point of greater than 120° C.

Suitable as matrix materials for use at cooking surfaces are UV-curable or thermally curable polymers, such as, for example, polyvinyl alcohol, polyvinyl acetals, polyvinylpyrrolidone, polyolefins, polycarbonate, polyethylene terephthalate, perfluorinated polymers, such as, for example, polytetrafluorethylene, polyurethanes, such as, for example, silicone-modified polyurethanes, polyesters, epoxy resins, methacrylate resins, polyimides, cycloolefin copolymers, polyethersulfone, and mixtures of these constituents, polysiloxanes such as, for example, methyl polysiloxanes, phenyl polysiloxanes, methyl/phenyl polysiloxanes, polysiloxanes such as, for example, acrylate-modified, polyester-modified, polyurethane-modified, epoxide-modified, or nanoparticle-functionalized polysiloxanes, and/or silicones, silicone resins, polyester-modified, polyether-modified, or epoxide-functionalized silicone resins, silaxanes, silazanes, SiliXane, polysilsesquioxanes, UV-crosslinkable or thermally organically crosslinkable hybrid-polymeric sol-gel materials, hybrid-polymeric sol-gel materials, nanoparticle-functionalized sol-gel materials, sol-gel materials with nanoparticle fillers, and inorganic sol-gel materials. Involved as additives in this case are nanoparticle fillers, which are not incorporated into the sol-gel network, whereas nanoparticles in nanoparticle-functionalized sol-gel materials are incorporated reactively into the matrix network.

For example, UV-activated or thermal initiators for cationic or radical polymerization, such as triarylsulfonium salts, diaryliodinium salts (e.g., Irgacure 250), ferrocenium salts, benzoin derivatives, α-hydroxyalkyl phenones (e.g., Irgacure 184), α-aminoacetophenones (e.g., 2-methyl-1-[4-(methylthio)phenyl]-2-morpholinopropanone), acylphosphine oxides (e.g., Irgacure 819), or 1,5-diazabicyclo[4.3.0]non-5-ene (DBN) or 1,8-diazabicyclo[5.4.0]undec-7-ene can be added to the coating solution.

For improvement of screen-printing capability, dispersibility, prevention of defects and Bernard cells, it is possible to add auxiliary and pasting substances, defoamers, deaerators, levelers, wetting and dispersing additives, lubricating additives, flow-control additives, and substrate wetting additives to the coating solution.

Depending on the coating method in each case, it is also possible to add various flow-control agents, defoamers, deaerators, or dispersing additives, such as, for example, PEG, BYK 302, BYK 306, BYK 307, DC11, DC57, or Airex 931 or Airex 930 in order to achieve homogeneous layer thicknesses and a homogeneous distribution of the additives in the coating.

As was mentioned above, a temperature resistance of the matrix material of 140° C. is required in accordance with the invention. Characteristic of heat-resistant matrix materials is that, after a thermal treatment at a temperature of at least 140° C. for 2 hours, they show no yellowing and no significant reduction in transmittance as well as no significant increase in the sheet resistance. Regarded as a significant reduction in transmittance is a change in transmittance of greater than 5%. Regarded as a significant increase in sheet resistance is a change in sheet resistance of greater than 10%.

Metal alkoxides are preferably used as sol-gel starting materials, preferably alkoxysilanes, such as, for example, TEOS (tetraethoxysilane), aluminum alkoxides, titanium alkoxides, zirconium alkoxides, and/or organometallic alkoxides. Preferably utilized is a tetraalkoxysilane Si(OR¹)₄ (with R¹=methyl, ethyl, propyl, iso-propyl, butyl, sec. butyl, phenyl), or an aluminum alkoxide or a titanium alkoxide or a zirconium alkoxide in combination with an alkoxysilane Si(OR¹)₃R², which has an organically crosslinkable functionality (R²=alkyl chain functionalized with glycidoxy, methacryloxy, acryl, vinyl, allyl, amino, mercapto, isocyanato, epoxy, acrylate, methacrylate . . . ). Organically crosslinkable alkoxysilanes can be, for example, GPTES (glycidyloxypropyltriethoxysilane), MPTES (methacryloxypropyltriethoxysilane), GPTMS (glycidyloxypropyltrimethoxysilane), MPTMS (methacryloxypropyltrimethoxysilane), VTES (vinyltriethoxysilane), ATES (allyltriethoxysilane), APTES (aminopropyltriethoxysilane), MPTES (mercaptopropyltriethoxysilane), or ICPTES (3-isocyanatopropyltriethoxysilane). As desired, another metal alkoxide can also be utilized, such as, for example, Zr(OR¹)₄, Ti(OR¹)₄, Al(OR¹)₃—for example, zirconium tetrapropoxide, titanium tetraethoxide, and aluminum secondary butoxide. As desired, another organoalkoxysilane can also be utilized, such as, for example, Si(OR¹)₃R³, Si(OR¹)₂R³₂, Si(OR¹)R³₃ (with R¹=methyl, ethyl, propyl, butyl, sec. butyl; R³=methyl, phenyl, ethyl, iso-propyl, butyl, sec. butyl)—for example, MTEOS (methyltriethoxysilane), PhTEOS (phenyltriethoxysilane), and DEMDEOS (dimethyldiethoxysilane). The preparation of the (sol-gel) hydrolyzate is accomplished by specific reaction of the monomers with H₂O. Preferably, this is carried out in the presence of an acid, such as, for example, HCl, H₂SO₄, paratoluoenesulfonic acid, or acetic acid. The pH of the aqueous hydrolysis solution is preferably <4. In a special embodiment, the hydrolysis can also be carried out in alkaline medium (e.g., NH₃, NaOH). In another special embodiment, the hydrolysis is accomplished using an aqueous nanoparticle dispersion. The degree of crosslinking of the hydrolyzate is adjusted through the ratio of H₂O to hydrolyzable monomers. The degree of crosslinking in this case is preferably 5-50%, more preferably 11-40%, most preferably 15-35%. The degree of crosslinking is determined by ²⁹Si-NMR. The viscosity of the hydrolyzate is 5-30 mPas, preferably 9-25 mPas. The residual solvent content is preferably <10 wt %.

Preferably, the volume percentage of the alkoxysilane with organically crosslinkable functionality is chosen such that the nanoscale additives are dispersed sterically in the liquid state, but are in contact with the layer in the cured state, that is, are in electrically conductive connection.

The matrix can be dielectric or non-dielectric. In a special embodiment, the matrix material can also itself be conductive. For example, this case can involve so-called conjugated polymers, such as, for example, poly(3,4-ethylenedioxythiophene)poly(styrenesulfonate) (PEDOT/PSS), but, above all, temperature-resistant silanes with one or more conductive groups.

The matrix can additionally contain nanoparticles made of oxidic materials, such as TiO₂ (anatase and/or rutile), ZrO₂ (amorphous, monoclinic, and/or tetragonal phase), Ca or Y₂O₃-doped ZrO₂, MgO-doped ZrO₂, CeO₂, Gd₂O₃-doped CeO₂, Y-doped ZrO₂, SiO₂, B₂O₃, Al₂O₃ (α, γ, or amorphous form), SnO₂, ZnO, Bi₂O₃, Li₂O, K₂O, SrO, NaO, CaO, BaO, La₂O₃, and/or HfO₂, boehmite, andalusite, mullite, and the mixed oxides thereof. Preferably, the matrix can include SiO₂-containing nanoparticles.

The matrix exhibits a refractive index in the range of 1.4 to 1.6, preferably in the range of 1.45 to 1.57.

The transparent conductive layer preferably has a thickness of 10 nm to 500 μm, preferably 20 nm to 100 μm, more preferably 100 nm to 10 μm.

The light transmittance of the transparent electrical conductor, composed of a substrate and a conductive layer, is at least 75%, preferably 85%, more preferably 90% of the transmittance of the substrate (measured with a transparency measuring instrument (Haze-Gard Plus) in accordance with ASTM D 1003) for a substrate thickness of 4 mm and at wavelengths greater than 450 nm.

The haze value of the transparent electrical conductor, composed of a substrate and a conductive layer, should be less than 15%, preferably less than 5%, more preferably <3% (measured with a transparency measuring instrument (Haze-Gard Plus) in accordance with ASTM D 1003).

The highly conductive additives are generally inorganic materials/particles (metals, alloys, non-oxidic and oxidic materials), which preferably have a fiber-like morphology.

The aspect ratio (length to diameter) of the fiber-like particles in this case is greater 10, preferably greater than 100, most preferably greater than 200. The mean aspect ratio is determined on the basis of scanning electron micrographs of 50 fibers.

The aspect ratio in this case is 10-100,000, preferably 50-10,000, most preferably 85-1000.

The mean diameter of the fiber-like additives in this case is less than 500 nm, preferably less than 200 nm, more preferably less than 100 nm.

The mean diameter in this case is preferably 40-150 nm, more preferably 50-100 nm. The mean diameter is determined on the basis of scanning electron micrographs of 100 fibers.

The highly conductive additive is preferably composed of a material with an electrical conductivity greater than 10⁴ S/m, preferably greater than 3×10⁷ S/m, more preferably greater than 5×10⁷ S/m.

In the preferred embodiment, the preferred material of the conductivity additives in the bulk state (thickness of less than 100 μm, preferably less than 10 μm, more preferably less than 1 μm) has a transmission of less than 10%, preferably less than 5%, more preferably less than 1%. This means that, preferably, the materials utilized show a nearly 100% absorption of visible light, even for a small material thickness.

As a conductivity additive, it is possible to utilize metallic nanowires or nanotubes (for example, those made of silver, copper, gold, aluminum, nickel, platinum, palladium, etc. and the alloys thereof (e.g., AuAg), coated metallic nanowires (e.g., nickel-coated copper nanowires; polymer-coated metallic nanowires), conductive doped oxide particles and/or nanowires (ITO, AZO, ATO, etc.), carbon nanomaterials and micromaterials (e.g., single-walled and multi-walled carbon nanotubes, graphene, soot), inorganic non-oxidic nanowires (e.g., metal chalcogenides), and fibers made of conductive polymers as well as combinations of these conductivity additives. Especially preferably, metallic nanowires made of silver or copper are utilized.

In a special embodiment, the conductive additives are coated with a barrier coating or a highly transparent sealing layer, which impedes the gradual degradation occurring over time and increases long-term stability. Used as a barrier coating are organic and inorganic materials; in particular, in this case, for example, perfluorinated polymers, parylenes, poly(vinylpyrrolidone), sol-gel materials, and metals (for example, those with low oxidation tendency, such as, for example, nickel) are utilized.

In a special embodiment, the conductivity additives utilized are those that are modified on the surface for better dispersion. For example, surface-active surfactants or oligomers/polymers can be utilized for this.

The volume percentage of the conductivity additive inside the transparent conductive material in this case is 0.1-30%, preferably 0.2-15%, especially preferably 0.4-10%.

Methods for producing selected conductivity additives will be outlined below:

Ag nanowires can be prepared in large quantities via the “polyol synthesis” by liquid-phase reduction of silver salts (e.g., silver nitrate) with the assistance of a polyol (e.g., ethylene glycol). In this case, the anisotropic growth of nanowires is achieved by addition of poly(vinylpyrrolidone) (PVP), which kinetically inhibits/controls the growth of various facets of silver crystals. Silver nanowires with diameters of approximately 40 to 120 nm and an aspect ratio of up to 1000 can be produced in this way. With additional air sparging, the yield of Ag nanowires can be clearly increased.

Cu nanowires with a high aspect ratio can be produced via electrospinning. First of all, a solution of copper acetate and poly(vinyl acetate) is electrospun onto a glass substrate. These fibers have a diameter of approximately 200 nm. In a second step, the copper-containing polymer fibers are heated to 500° C. in air (2 h) in order to eliminate the organic constituents. The resulting dark brown CuO nanowires are then reduced by means of a heating step at 300° C. (1 h) in hydrogen to yield (red) metallic copper.

The preparation of Cu nanowires is further possible via hydrothermal synthesis. In this case, copper (II) chloride, for example, is reduced in an aqueous solution of octadecylamine (ODA) under hydrothermal conditions at 120-180° C. At high temperatures (180° C.) and elevated ODA concentration, monocrystalline Cu nanowires with diameters in the range of 50 nm≦d≦100 nm and an aspect ratio of greater than 10⁵ are formed.

The production of Cu nanowires via the reduction of Cu(NO₃)₂ in an aqueous solution of hydrazine, NaOH, and ethylendiamine has also been reported. This method is suitable for producing large quantities of Cu nanowires. In a further step, the wires can also be sheathed with a nickel layer, as a result of which the oxidation resistance is increased.

The nanoscale additives can be present in dispersed form in a suitable solvent, such as, for example, ethanol or isopropanol.

Surprisingly, it was found that especially good opto electrical properties are obtained when the zeta potential of the matrix material is adjusted to the zeta potential of the dispersion of nanoscale additives. On the one hand, the zeta potential of the matrix material can be adjusted, for example, by variation of the sol-gel starting materials and/or by doping with another sol-gel starting material, such as, for example, a metal alkoxide, a metal hydroxide, a metal halide, a metal nitrate, a metal acetylacetonate, a metal acetate, a metal carbonate, and/or a metal oxide. In this case, the metal in these metal compounds can be a heavy metal or a light metal. The adjustment of the zeta potential of the matrix material can additionally be accomplished by addition of a suitable dispersant. On the other hand, the zeta potential of the dispersion of nanoscale additives can be adjusted by addition of a suitable dispersant—for example, by addition of an acid, such as, for example paratoluenesulfonic acid, a polyvalent acid, such as, for example citric acid, polyacrylic acid, or a base, such as, for example polyethylenimine. An adjustment to positive zeta potentials has proven to be especially advantageous.

The targeted use of a temperature-resistant substrate as well as a temperature-resistant matrix and highly conductive particles with fiber-like geometry makes it possible to provide a transparent electrical conductor that has both a low sheet resistance and a sufficiently high transmittance, while exhibiting, at the same time, high temperature resistance.

Special glass substrates are preferred for the substrate. Such special glass substrates can be glass ceramics, particularly transparent dyed lithium aluminosilicate (LAS) glass ceramics, transparent LAS glass ceramics or magnesium aluminosilicate glass ceramics or lithium disilicate glass ceramics, or silicate glasses, such as, for example, borosilicate glasses, zinc borosilicate glasses, boroaluminosilicate glasses, aluminosilicate glasses, alkali-free glasses, soda-lime glasses, or a composite material made from the aforementioned glasses and/or glass ceramics.

Preferably, a thermoshock-resistant special glass or a glass ceramic with a coefficient of thermal expansion of less than 4.0×10⁻⁶/K, preferably less than

3.4×10⁻⁶/K, is used. Preferably, a borosilicate glass or a lithium aluminosilicate glass ceramic with high-quartz mixed crystal phase or keatite is used. The crystal phase content in this case is 60-85%.

The substrates used preferably contain less than 1000 ppm, more preferably less than 500 ppm, most preferably less than 200 ppm, arsenic and/or antimony. In one embodiment, the glass ceramic used is free of arsenic and antimony.

In a special embodiment, a prestressed special glass substrate is used, in particular boroaluminosilicate glasses (such as, for example, SCHOTT Xensation™, Corning Gorilla™ I-III, Asahi Dragontrail™). The prestressing in this case can be induced chemically or thermally.

The substrate in this case can be rigid or flexible.

The substrate in this case can be planar or bent or deformed.

The substrate can have mechanically processed or even etched surfaces.

Preferred thicknesses of the substrate lie in the range of 10 μm to 6 cm, more preferably 30 μm to 2 cm, even more preferably 50 μm to 6 mm, most preferably 1 mm to 6 mm.

Substrates that are smooth on both sides or nobby on one side can be used, with particularly the nobby substrates being provided with an equalizing layer (e.g., one made of PU or silicones or silicone resins) that satisfies the use properties.

In the case of transparent special glass substrates, the light transmittance of the substrate is greater than 80%, preferably greater than 90%, for a substrate thickness of 4 mm and at wavelengths of greater than 450 nm in the visible region. The light transmittance of the coated special glass substrates (substrate and transparent conductive layer) in the visible region is greater than 60%, preferably greater than 70%, most preferably greater than 85%. The coated special glass substrate is further characterized in that the haze value is less than 15%, preferably less than 5%, most preferably less than 3%.

In the case of special glass substrates composed of transparent single-colored glass ceramics, the light transmittance of the substrate in the visible range (light transmittance in accordance with ISO 9050:2003, 380-780 nm) is 0.8-10% for a substrate thickness of 4 mm. The coated special glass substrate in this case is characterized by a transmittance of 0.6-9% in the visible range. The transmittance of the special glass substrates is 45% in the infrared in the range of 850 nm to 970 nm. The transmittance of the coated special glass substrate is 40% in the infrared in the range of 820 nm to 970 nm.

Preferably, the substrate glasses used are those utilized in the area of white goods or household appliances, such as, for example, those used for baking and cooking appliances, microwaves, refrigerators, steamers, control panels for such appliances, gas cooking appliances, washers, or dishwashers. Especially preferably, the substrate glasses used are those utilized for cooktops, oven panels, or fireplace viewing panels.

Preferably utilized as (coating) methods for applying the matrix precursors containing the conductivity additives dispersed therein (that is, the coating material) are printing methods, in particular screen printing, doctor-blading, ink-jet printing, offset printing, or pad printing as well as spraying methods, roll coating, and spin coating.

The transparent conductive layer can be cured by UV irradiation or thermally. In the case of thermal curing in the temperature range of 150-500° C. for 10 min to 3 h, the curing is carried out such that a sintering or fusion together of conductivity additives in contact with one another can occur, as a result of which contact resistances between the conductivity additives are reduced. Such sintering or fusion can be detected by means of a scanning electron microscope.

In a preferred embodiment (in the case of UV and thermal curing), an additional thermal post-treatment can be carried out at 150-500° C., preferably at 200-250° C., for 5 min-4 h, preferably 10 min-2 h, more preferably for 20 min-1 h, in order to achieve sintering or an extension/increase in size of the sintered regions. Furthermore, it is also possible (during the curing or drying) to apply pressure, preferably >1 bar, in order to increase the connectivity of the conductivity additives. In another embodiment, the shrinkage of the matrix during drying is exploited to increase the connectivity.

In another preferred embodiment, the solution of the conductivity additives is filtered under pressure and/or centrifuged prior to being added to the matrix material, as a result of which, on the one hand, residues, such as high-boiling solvents, stabilizers, and nanoparticles, can be removed and, on the other hand, it is also possible to press the conductivity additives together for a better electrical connectivity.

In another special embodiment, an increase in connectivity is achieved by utilizing a conductive polymer as a matrix material or as a sheath material for the nanowires.

The substrate in this case is preferably coated with the transparent conductive layer in the display region or in the cool region of the cooking surface.

The substrate, furnished with a transparent conductive layer, preferably serves to provide a cooking surface capable of having a touch display.

The substrate in this case is preferably provided with a transparent conductive layer on the bottom side.

The transparent electrical conductor in this case is characterized in that the coating material applied (matrix material plus nanoscale additives) exhibits a sheet resistance of less than 500 ohm/sq, preferably less than 250 ohm/sq, most preferably less than 150 ohm/sq (measured in accordance with the four-point method and/or the vortex method).

The invention makes it possible, through specific use of matrix and highly conductive particles with fiber-like geometry, to provide a transparent electrical conductor that has a transparent conductive layer, which can be applied by a simple coating method and exhibits a low sheet resistance, a high transmission, and a high temperature resistance and resistance to corrosion.

The transparent conductive layer can be applied in a laterally structured manner in one or more subregions on the substrate (for example, in the nm, μm, mm, or cm range) or it can be applied to the entire surface. Such a structuring enables, for example, the creation of single-touch sensor electrodes or structured fields made up of single-touch sensor electrodes in the cool region of the cooktop. A full-area application of the transparent conductive layer, preferably in a subregion of the substrate also makes it possible, for example, to provide a touch field (touch screen) with spatial resolution, in which case, by way of example, the spatial resolution is achieved by analysis of the difference signals at the corners.

In a preferred embodiment, a transparent substrate is provided with one or more decorative coatings, such as, for example, colored or transparent decorations, with it being possible for the colored decorations to be pigmented. In another preferred embodiment, a transparent substrate, furnished with one or more functional coatings, is used. These decorative and/or functional coatings can be located in this case on the same side as the transparent conductive coating material or on the opposite side. The additional coatings can be applied to cover the entire area in this case or can also be structured, such as, for example, cooking zone markings or a recess for a display.

Furthermore, a plurality of layers of the transparent conductive layer can be applied to the substrate. In a special embodiment, a dielectric layer and/or a layer acting as an antireflection layer is situated between a plurality of conductive layers. For example, the antireflection layer can be composed of silicon oxide and/or silicon nitride. Such a layer structure makes it possible, for example, to create a spatially resolved capacitive multitouch sensor.

### Exemplary Embodiment 1

For the production of silver nanowires, the solvent and reductant ethylene glycol is taken and brought to a temperature of 130° C. Afterward, 0.25 molar polyvinylpyrrolidone (PVP) solution and a 0.25 molar silver nitrate solution are added along with other additives, such as, for example, salt solutions. After a synthesis time of two hours, silver nanowires with a mean diameter of 95 nm and a mean length of 25 μm are obtained. The ethylene glycol as well as the PVP are removed via several centrifugation steps and replaced by ethanol. The ethanolic silver nanowire dispersion is blended and stirred with a sol-gel binder based on tetraethoxysilane in a ratio of 8:1 in a flask. The coating lacquer is applied onto a transparent glass ceramic (SCHOTT Ceran Cleartrans®) with a spiral dumbbell and produces a wet-film layer thickness of ≦10 μm. After thermal curing at 200° C. for one hour, a transparent conductive layer with a layer thickness of 0.5 μm and a volume percentage of silver nanowires of approximately 2% is obtained. The sheet resistance is 12 ohm/sq. The transmittance is 80% and the haze value is 13%.

### Exemplary Embodiment 2

The ethanolic silver nanowire dispersion in accordance with Exemplary Embodiment 1 is blended and stirred with a sol-gel binder based on tetraethoxysilane in a ratio of 2:1 in a flask. The coating lacquer is applied onto a transparent glass ceramic (SCHOTT Ceran Cleartrans®) with a spiral dumbbell and a wet-film thickness of ≦10 μm is produced. After thermal curing at 200° C. for one hour, a transparent conductive layer with a layer thickness of 0.6 μm and a volume percentage of silver nanowires of approximately 0.5% is obtained. The sheet resistance is 40 ohm/sq. The transmittance is 82% and the haze value is 9%.

### Exemplary Embodiment 3

The ethanolic silver nanowire dispersion in accordance with Exemplary Embodiment 1 is blended and stirred with a sol-gel binder based on tetraethoxysilane in a ratio of 2:1 in a flask. The coating lacquer is applied onto a boroaluminosilicate glass (SCHOTT Xensation™) with a spiral dumbbell and a wet-film thickness of ≦10 μm is produced. After thermal curing at 200° C. for one hour, a transparent conductive layer with a layer thickness of 0.6 μm and a volume percentage of silver nanowires of approximately 0.5% is obtained. The sheet resistance is 40 ohm/sq. The transmittance is 81% and the haze value is 8%.

### Exemplary Embodiment 4

A commercially available ethanolic silver nanowire dispersion containing nanowires with a mean wire diameter of 40 nm and a mean wire length of 35 μm and a sol-gel binder based on tetraethoxysilane are blended and stirred in a ratio of 4:1 in a flask. The coating lacquer is applied onto a transparent glass ceramic (SCHOTT Ceran Cleartrans®) with a spiral dumbbell and a wet-film thickness of ≦10 μm is produced. After thermal curing at 200° C. for one hour, a transparent conductive layer with a layer thickness of 0.6 μm and a volume percentage of silver nanowires of approximately 1% is obtained. The sheet resistance is 10 ohm/sq. The transmittance is 82% and the haze value is 9%.

### Exemplary Embodiment 5

A commercially available ethanolic silver nanowire dispersion containing nanowires with a mean wire diameter of 40 nm and a mean wire length of 35 μm and a silicone resin solution (SILRES® REN80) are blended and stirred in a ratio of 4:1 in a flask. The coating lacquer is applied onto a transparent glass ceramic (SCHOTT Ceran Cleartrans®) with a spiral dumbbell and a wet-film thickness of ≦10 μm is produced. After thermal curing at 200° C. for one hour, a transparent conductive layer with a layer thickness of 0.7 μm and a volume percentage of silver nanowires of approximately 1% is obtained. The sheet resistance is 14 ohm/sq. The transmittance is 84% and the haze value is 8%.

### Exemplary Embodiment 6

A commercially available ethanolic silver nanowire dispersion containing nanowires with a mean wire diameter of 40 nm and a mean wire length of 35 μm and a sol-gel binder based on aluminum secondary butoxide are blended and stirred in a ratio of 1:4 in a flask. The coating lacquer is applied onto a transparent glass ceramic (SCHOTT Ceran Cleartrans®) with a spiral dumbbell and a wet-film thickness of ≦10 μm is produced. After thermal curing at 200° C. for one hour, a transparent conductive layer with a layer thickness of 0.2 μm is obtained. The sheet resistance is 35 ohm/sq. The transmittance is 83% and the haze value is 4%.

### Exemplary Embodiment 7

A commercially available ethanolic silver nanowire dispersion containing nanowires with a mean wire diameter of 40 nm and a mean wire length of 35 μm is centrifuged. After the ethanol has been decanted, terpineol is added as a high-boiling solvent. The silver nanowire dispersion is blended and stirred with a sol-gel binder based on aluminum secondary butoxide in a ratio of 40:1 in a flask. The coating lacquer is applied onto a transparent glass ceramic (SCHOTT Ceran Cleartrans®) with a spiral dumbbell and a wet-film thickness of ≦10 μm is produced. After thermal curing at 200° C. for ninety minutes, a transparent conductive layer is obtained. The sheet resistance is 8 ohm/sq. The transmittance is 73% and the haze value is 14%.

### Exemplary Embodiment 8

A commercially available ethanolic silver nanowire dispersion containing nanowires with a mean wire diameter of 40 nm and a mean wire length of 35 μm is centrifuged. After the ethanol has been decanted, a terpineol-ethanol mixture in a volume ratio of 1:1 is added as solvent. The silver nanowire dispersion is blended and stirred with a sol-gel binder based on aluminum secondary butoxide in a ratio of 40:1. The coating lacquer is applied onto a transparent glass ceramic (SCHOTT Ceran Cleartrans®) with a spiral dumbbell and a wet-film thickness of ≦10 μm is produced. After thermal curing at 200° C. for ninety minutes, a transparent conductive layer is obtained. The sheet resistance is 150 ohm/sq. The transmittance is 80% and the haze value is 9%.

### Exemplary Embodiment 9

A commercially available ethanolic silver nanowire dispersion containing nanowires with a mean wire diameter of 40 nm and a mean wire length of 35 μm and a sol-gel binder based on tetraethoxysilane as a SiO₂ precursor and sodium hydroxide as a catalyst are blended and stirred in a ratio of 20:1 in a flask. The coating lacquer is applied onto a transparent glass ceramic (SCHOTT Ceran Cleartrans®) with a spiral dumbbell and a wet-film thickness of ≦10 μm is produced. After thermal curing at 200° C. for one hour, a transparent conductive layer is obtained. The sheet resistance is 41 ohm/sq. The transmittance is 83% and the haze value is 8%.

### Exemplary Embodiment 10

A commercially available ethanolic silver nanowire dispersion containing nanowires with a mean wire diameter of 40 nm and a mean wire length of 35 μm and a sol-gel binder based on tetraethoxysilane as a SiO₂ precursor and aqueous ammonia as a catalyst are blended and stirred in a ratio of 20:1 in a flask. The coating lacquer is applied onto a transparent glass ceramic (SCHOTT Ceran Cleartrans®) with a spiral dumbbell and a wet-film thickness of ≦10 μm is produced. After thermal curing at 200° C. for one hour, a transparent conductive layer is obtained. The sheet resistance is 21 ohm/sq. The transmittance is 78% and the haze value is 9%.

### Exemplary Embodiment 11

A commercially available ethanolic silver nanowire dispersion containing nanowires with a mean wire diameter of 40 nm and a mean wire length of 35 μm and a base-catalyzed sol-gel binder based on tetraethoxysilane and methyltriethoxysilane as SiO₂ precursors are blended and stirred in a ratio of 2:1 in a flask. The coating lacquer is applied onto a transparent glass ceramic (SCHOTT Ceran Cleartrans®) with a spiral dumbbell and a wet-film thickness of ≦10 μm is produced. After thermal curing at 420° C. for ten minutes, a transparent conductive layer is obtained. The sheet resistance is 34 ohm/sq. The transmittance is 86% and the haze value is 3%.

### BRIEF DESCRIPTION OF THE DRAWINGS

The invention will be explained in detail below on the basis of exemplary embodiments illustrated in the drawings. Shown are:

FIG. 1 an electrically conductive, transparent conductor in schematic side view;

FIG. 2 an alternative embodiment variant of a transparent electrical conductor in side view and schematic illustration;

FIG. 3 another alternative of a transparent electrical conductor in side view and schematic illustration;

FIG. 4 a cooking surface in plan view, which is coated in a subregion with a structured transparent conductive layer;

FIG. 5 a cooking surface in plan view, which is coated over the entire area of a subregion with a transparent conductive layer; and

FIG. 6 a view onto the back side of a cooking surface, in perspective illustration, with two structured transparent conductive layers, which are separated by an electrically insulating layer.

### DETAILED DESCRIPTION

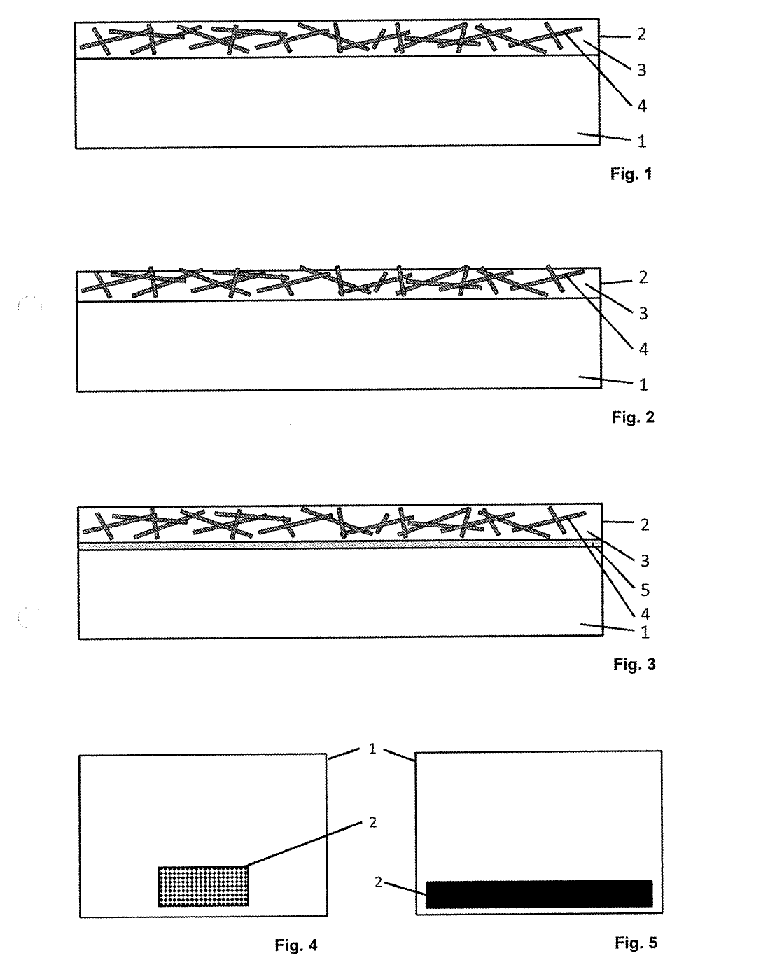

FIG. 1 shows a transparent substrate 1, composed of a glass or glass ceramic on which a conductive layer 2 is applied. The conductive layer 2 is composed of a matrix layer 3 in which highly conductive additives 4 are embedded in the form of nanowires or nanotubes. These additives 4 are present in the form of a network and are in electrically conductive contact with one another so as to form the conductive layer.

In the exemplary embodiment according to FIG. 2, a constitution similar to that of FIG. 1 is chosen, although some of the additives protrude beyond the surface of the matrix layer 3 so as to afford electrical contact there.

In accordance with the exemplary embodiment according to FIG. 3, a contact region 5 is provided between the substrate surface and the conductive layer 2. At least a part of the additives are in electrically conductive contact with this contact region 5. The contact region 5 can also be an electrically conductive metal layer, for example, which is applied in a structured manner by a liquid coating method.

FIGS. 4 and 5 show two exemplary embodiments of a transparent electrical conductor in the form of a cooking surface. In this case, conductive layers 2 can be applied to the bottom side of a substrate 1, which is generally composed of a glass ceramic. Whereas, in the exemplary embodiment according to FIG. 4, a subregion is provided with a structured transparent conductive coating, a full-area transparent conductive coating is applied in FIG. 5 in a subregion of the cooking surface.

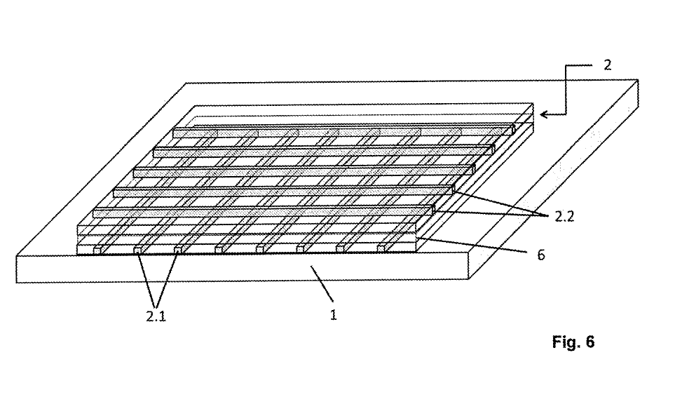

FIG. 6 shows a substrate 1 in the form of a special glass, on which two strip-shaped structured conductive layers 2.1 and 2.2 are applied, with the strips being arranged crosswise with respect to each other. Arranged between the layers 2.1 and 2.2 is an electrically insulating layer 6. In this way, an x-y resolved capacitive touch panel can be created.

What is claimed is:

1. A transparent electrical conductor, comprising:
a transparent substrate formed from a material selected from the group consisting of glass, glass-ceramic, a composite material glass, a composite material having glass ceramic, and combinations thereof; and
an electrically conductive layer on the transparent substrate, the electrically conductive layer having a plurality of electrically conductive, nanoscale additives, the additives being in electrically conductive contact with one another in order to form the electrically conductive layer, the additives being embedded in a matrix layer at least in some regions, the matrix layer being formed by a transparent matrix material, wherein the transparent electrical conductor has a temperature resistance of at least 140° C.

2. The transparent electrical conductor according to claim 1, wherein the electrically conductive layer has a scratch resistance of at least 500 g and/or a sheet resistance of less than 500 ohm/sq.

3. The transparent electrical conductor according to claim 1, further comprising a light transmission (λ) of at least 75% for a substrate thickness of 4 mm and at wavelengths greater than 450 nm and/or a haze value of less than 15%.

4. The transparent electrical conductor according to claim 1, wherein the transparent matrix material comprises a material selected from the group consisting of UV-curable polymers, thermally curable polymers, silicone, UV-crosslinkable or thermally organically crosslinkable hybrid-polymeric sol-gel materials, hybrid-polymeric sol-gel materials, nanoparticle-functionalized sol-gel materials, sol-gel materials containing nanoparticle fillers, and inorganic sol-gel materials exhibiting a temperature resistance of at least 140° C.

5. The transparent electrical conductor according to claim 4, wherein the transparent matrix material comprises at least one condensed and/or hydrolyzed monomer of metal alkoxides.

6. The transparent electrical conductor according to claim 5, wherein the metal alkoxides are selected from the group consisting of silicon, zirconium, titanium, aluminum, organometallic alkoxides, and combinations thereof.

7. The transparent electrical conductor according to claim 5, wherein the transparent matrix material further comprises a tetraalkoxysilane Si(OR¹)₄ with R¹=methyl, ethyl, propyl, iso-propyl, butyl, sec. butyl, phenyl, or another metal alkoxide.

8. The transparent electrical conductor according to claim 7, wherein the transparent matrix material further comprises another alkoxysilane Si(OR¹)₃R², which has an organically crosslinkable functionality (with R²=alkyl chain functionalized with glycidoxy, methacryloxy, acryl, vinyl, allyl, amino, mercapto, isocyanato) and/or another metal alkoxide and/or another organoalkoxy silane Si(OR¹)₃R³ or Si(OR¹)₂R³₂ or Si(OR¹)R³₃ with R³: methyl, phenyl, ethyl, iso-propyl, butyl, sec. butyl.

9. The transparent electrical conductor according to claim 1, wherein the transparent matrix material has a zeta potential of adjusted to a zeta potential of the additives.

10. The transparent electrical conductor according to claim 9, wherein the transparent matrix material further comprises, as zeta potential adjustors, materials selected from the group consisting of sol-gel starting materials, doping with another sol-gel starting material, and a suitable dispersant.

11. The transparent electrical conductor according to claim 10, wherein the doping with another sol-gel starting material comprises dopants selected from the group consisting of metal alkoxide, a metal hydroxide, a metal halide, a metal nitrate, a metal acetylacetonate, a metal acetate, a metal carbonate, a metal oxide, and combinations thereof.

12. The transparent electrical conductor according to claim 9, wherein the additive further comprises, as zeta potential adjustors, an acidic dispersant or a basic dispersant.

13. The transparent electrical conductor according to claim 12, wherein the acidic dispersant comprises an acid selected from the group consisting of paratoluenesulfonic acid, polyvalent acid, citric acid, and polyacrylic acid, and wherein the basic dispersant comprises polyethylenimine.

14. The transparent electrical conductor according to claim 1, wherein the transparent matrix material comprises a volume percentage of alkoxysilane with organically crosslinkable functionality sufficient such that the additives are sterically dispersed in a liquid state, but are in contact with one another in a cured state.

15. The transparent electrical conductor according to claim 1, wherein the additives have a fiber-like morphology having an aspect ratio of length to diameter that lies in a range of 10 to 100,000.

16. The transparent electrical conductor according to claim 1, wherein the additives comprise a material having an electrical conductivity of greater than 10⁴ S/m.

17. The transparent electrical conductor according to claim 1, wherein the additives comprise silver, copper, gold, and alloys thereof.

18. The transparent electrical conductor according to claim 1, wherein the additives have a mean diameter that lies in a range of 40 to 150 nm.

19. The transparent electrical conductor according to claim 1, wherein the additives further comprise a coating layer having a low oxidation tendency.

20. The transparent electrical conductor according to claim 1, wherein the material of the transparent substrate is selected from the group consisting of single colored glass ceramic, lithium aluminosilicate (LAS) glass ceramic, magnesium aluminosilicate glass ceramic, silicate glass, boroaluminosilicate glass, aluminosilicate glass, alkali-free glass, soda-lime glass, and any composites thereof.

21. The transparent electrical conductor according to claim 1, wherein the transparent substrate has a coefficient of thermal expansion of less than 4.0×10⁻⁶/K.

22. A method for the production of a transparent electrical conductor, comprising:
dispersing and embedding a plurality of electrically conductive nanoscale additives in a transparent matrix material; and
applying the transparent matrix material directly or indirectly onto a substrate to form an electrically conductive layer.

23. The method according to claim 22, wherein, prior to the step of dispersing and embedding, the additives and/or the transparent matrix material are both present in a solvent selected from the group consisting of a low-boiling solvent, a high-boiling solvent, and a solvent mixture composed of at least one low-boiling solvent and at least one high-boiling solvent.

24. The method according to claim 22, further comprising curing the electrically conductive layer and, after curing, subjecting the electrically conductive layer to a thermal post-treatment at 150 to 500° C. for 5 minutes to 4 hours.

25. The method according to claim 22, the transparent matrix material comprises at least one condensed and/or hydrolyzed monomer of metal alkoxides, preferably silicon, zirconium, titanium, aluminum, and/or organometallic alkoxides, preferably Si(OR)₄, SiR(OR)₃, or SiR₂(OR)₂, with R=organic functionality and OR=alkoxide functionality.

26. The method according to claim 22, wherein the step of applying the transparent matrix material comprises a process selected from the group consisting of screen-printing, doctor-blade lacquering, ink-jetting, spray lacquering, roll-coating lacquering, spin-coating lacquering, and pad lacquering.

27. The method according to claim 22, further comprising dispersing metallic nanowires or nanotubes as the additives in the transparent matrix material.

28. The method according to claim 22, wherein the step of applying the transparent matrix material comprises applying two or more layers onto the substrate.

29. The method according to claim 28, further comprising introducing a layer having a dielectric material and/or an antireflection layer between the two or more layers.

30. The method according to claim 22, wherein the step of applying the transparent matrix material comprises applying the transparent matrix material to the substrate in one or more subregions in a laterally structured manner.

31. The method according to claim 22, further comprising increasing connectivity between the additives by a process selected from the group consisting of a thermal post-treatment at 150 to 500° C. for 10 minutes to 3 hours, a treatment under pressure, exploiting matrix shrinkage during curing, utilizing a conductive polymer as matrix or sheath material for the additives.
